(19) United States
(12) Patent Application Publication
(10) Pub. No.: US 2025/0316961 A1
(43) Pub. Date: Oct. 9, 2025

(54) VERTICAL CAVITY SURFACE EMITTING LASER ARRAY WITHOUT IMPLANTATION

(71) Applicant: Lumentum Operations LLC, San Jose, CA (US)

(72) Inventor: Suning XIE, San Jose, CA (US)

(21) Appl. No.: 18/738,395

(22) Filed: Jun. 10, 2024

Related U.S. Application Data
(60) Provisional application No. 63/574,004, filed on Apr. 3, 2024.

(51) Int. Cl. H01S 5/183

(52) U.S. Cl. CPC H01S 5/18333; H01S 5/18361

(57) ABSTRACT

A vertical-cavity surface-emitting laser (VCSEL) emitter device includes a highly-doped cap layer; and a stacked structure comprising a top surface and an edge region. The highly-doped cap layer is arranged on the top surface. The stacked structure includes a bottom distributed Bragg reflector (DBR) mirror; a top DBR mirror; an active area arranged between the top DBR mirror and the bottom DBR mirror and configured to generate laser light; and at least one oxide layer, wherein an oxide aperture is formed through the at least one oxide layer for current confinement and optical index guiding. An isolation trench is arranged at the edge region, wherein the isolation trench extends through the highly-doped cap layer and into the stacked structure, including partially into the bottom DBR mirror, and wherein the isolation trench is configured to block current from spreading into the edge region via the highly-doped cap layer.

### CROSS-REFERENCE TO RELATED APPLICATION

This Patent Application claims priority to U.S. Provisional Patent Application No. 63/574,004, filed on Apr. 3, 2024, and entitled “VERTICAL CAVITY SURFACE EMITTING LASER ARRAY WITHOUT IMPLANTATION.” The disclosure of the prior Application is considered part of and is incorporated by reference into this Patent Application.

### TECHNICAL FIELD

The present disclosure relates generally to vertical cavity surface emitting laser (VCSEL) arrays.

### BACKGROUND

A VCSEL is a type of semiconductor laser diode (e.g., a laser resonator) with laser beam emission perpendicular to a top surface or a bottom surface of the device. VCSELs typically include two distributed Bragg reflector (DBR) mirrors arranged parallel to a wafer surface with an active region arranged between the two DBR mirrors. The active region includes one or more quantum wells for laser light generation. VCSELs are widely used in various applications, such as data communications, sensing, and optical interconnects, due to advantages over other types of lasers. For example, VCSELs typically have lower power consumption (e.g., VCSELs require much lower power to operate than other types of lasers, making them more energy-efficient and cost-effective), are capable of high-speed operation (e.g., making VCSELs ideal for data communications and other applications that require high-speed signal transmission), have narrow beam divergence (e.g., the narrow beam divergence of VCSELs allows for high coupling efficiency with optical fibers and other components, making VCSELs easier to integrate into optical systems), and have high reliability (e.g., VCSELs have a long operating lifetime and are less prone to failure than other types of lasers).

Different applications, such as three-dimensional sensing and data communications, may use semiconductor lasers emitting at different wavelength bands. For example, short-range communications may use VCSELs emitting at around 850 nm, whereas long-range communications may use VCSELs emitting above 1.3 μm or even above 1.5 μm. Three-dimensional sensing applications, such as light detection and ranging (LiDAR), may use VCSELs emitting at different wavelengths, such as 905 nm and 940 nm, to enable varied functions.

A typical VCSEL has a sandwich structure mainly consisting of a top DBR, a bottom DBR, and an active region (e.g., an active layer) arranged between the top DBR and the bottom DBR. Each DBR is made of multiple alternatively stacked high-index layers and low-index layers, and each layer has an optical thickness of an odd integer multiple of ¼-lambda (λ/4, 3λ/4, . . . ), where an optical thickness of one lambda is the length of one wavelength divided by the refractive index. “High-index” means a relatively higher value of an optical refractive index, and “low-index” means a relatively lower value of an optical refractive index. Optionally, a DBR may include gradient layers that provide a smoother transition between different energy bands corresponding to high-index and low-index semiconductor materials. The top DBR, the active region, and the bottom DBR form an optical cavity with gain material.

### SUMMARY

In some implementations, a VCSEL emitter device includes a highly-doped cap layer; a stacked structure comprising a top surface and an edge region, wherein the highly-doped cap layer is arranged on the top surface, and wherein the stacked structure comprises: a bottom DBR mirror; a top DBR mirror arranged on the bottom DBR mirror; an active area formed by one or more active layers comprising one or more junctions, each junction including one or more quantum wells, wherein the active area is configured to generate laser light, and wherein the active area is arranged between the top DBR mirror and the bottom DBR mirror; and one or more oxide layers, wherein an oxide aperture is formed through the one or more oxide layers for current confinement and optical index guiding. The VCSEL emitter device further includes an isolation trench arranged at the edge region, wherein the isolation trench extends through the highly-doped cap layer and into the stacked structure, including contacting the one or more oxide layers and extending partially into the bottom DBR mirror, and wherein the isolation trench is configured to block current from spreading into the edge region via the highly-doped cap layer.

In some implementations, a VCSEL array device includes an emitter array region and an edge region that laterally surrounds the emitter array region; an emitter array comprising a plurality of emitters arranged in the emitter array region and that share a semiconductor surface, wherein the plurality of emitters include a plurality of peripheral emitters arranged at a periphery of the emitter array region, wherein each emitter of the plurality of emitters includes: a stacked structure comprising: a top DBR mirror; a bottom DBR mirror arranged on the top DBR mirror; an active area formed by one or more active layers comprising one or more junctions, each junction including one or more quantum wells, wherein the active area is configured to generate laser light, and wherein the active area is arranged between the top DBR mirror and the bottom DBR mirror; and one or more oxide layers, wherein an oxide aperture is formed through the one or more oxide layers for current confinement and optical index guiding in the active area; a highly-doped semiconductor layer arranged on the semiconductor surface for current spreading laterally in the emitter array region; and an optical output arranged over the top DBR mirror, wherein the emitter is configured to emit the laser light via the optical output; and an isolation trench that laterally surrounds the emitter array region, wherein the isolation trench laterally separates the emitter array region from the edge region, wherein the isolation trench extends through the highly-doped semiconductor layer into the stacked structure, including extending through the top DBR mirror, extending through the one or more active layers, contacting the one or more oxide layers, and extending partially through the bottom DBR mirror of each peripheral emitter of the plurality of peripheral emitters, and wherein the isolation trench is configured to block one or more currents from spreading from the emitter array region into the edge region where there is no oxide layer present for current confinement.

In some implementations, a method of manufacturing a VCSEL array device includes forming a stacked structure comprising an emitter array region and an edge region, wherein the stacked structure comprises: a bottom DBR mirror; a top DBR mirror having a top surface; one or more active layers arranged between the bottom DBR mirror and the top DBR mirror; and one or more epitaxial layers configured for oxidation; forming a highly-doped semiconductor layer on the top surface; forming, by etching, oxidation trenches that extend through the highly-doped semiconductor layer and into the stacked structure to expose the one or more epitaxial layers for oxidation; forming, by etching, an isolation trench at the edge region, wherein the isolation trench extends through the highly-doped semiconductor layer and into the stacked structure, including partially into the bottom DBR mirror, and wherein the isolation trench is configured to block current from spreading from the emitter array region into the edge region; forming the one or more oxide layers and an oxide aperture via oxidation of the one or more epitaxial layers configured for oxidation, wherein the oxide aperture is configured for current confinement and optical index guiding; forming one or more dielectric layers on the highly-doped semiconductor layer and within the isolation trench; and forming a contact layer on the highly-doped semiconductor layer.

### BRIEF DESCRIPTION OF THE DRAWINGS

FIG. 1A shows a top view of a VCSEL chip according to one or more implementations.

FIG. 1B shows a cross-sectional view taken along line X-X in FIG. 1A.

FIG. 2 is a flowchart of an example process associated with vertical cavity surface emitting laser array without implantation.

### DETAILED DESCRIPTION

The following detailed description of example implementations refers to the accompanying drawings. The same reference numbers in different drawings may identify the same or similar elements.

VCSEL arrays have been widely used for three-dimensional (3D) sensing applications such as facial recognition and automotive LiDAR. VCSEL arrays generate optical peak power from sub-watt to hundreds of watts, at an operating peak current of up to hundreds of amperes with pulse widths from nano seconds (<10 ns for automotive LiDAR) to milliseconds for facial recognition with a voltage up to of tens of volts. Various designs and fabrication processes are employed for performance and reliability.

In current design and fabrication processes, ion implantation is used for current confinement, such as in an area between a chip edge of a VCSEL chip and an oxide front in a perimeter of the VCSEL chip. The ion implantation prevents current spreading via a highly-doped (e.g., p+) cap layer to an edge area of the VCSEL chip, located outside of an oxide aperture/emitting area, and improves lasing efficiency.

Individual chips (e.g., chips made of III-V materials, such as GaAs chips) may be referred to as dies. “Wafer dicing” refers to a process step during which dies are separated from each other on a semiconductor wafer by scribing, cutting by laser, or physically sawing areas between the individual dies to separate the dies. The areas between the individual dies at which separation occurs may be referred to as dicing streets or scribe lines. Dicing is carried out after the semiconductor wafer has been processed (e.g., after the VCSEL emitter arrays on each VCSEL chip are formed). A dicing street may be etched in the semiconductor wafer to prevent damage to a sidewall that occurs from a dicing process, and the sidewall may be covered with a dielectric for environmental reliability. In the absence of the dicing street, the ion implantation also reduces a leakage current and prevents junctions from breakdown due to damage that may occur to a junction sidewall from the dicing process. However, these designs and processes may also introduce different performance and long-term reliability issues and may increase the fabrication complexity and costs of the VCSEL chip.

The ion implantation and the dicing street may cause one or more issues. For example, the ion implantation may cause performance drifts in VCSEL operation, the ion implantation may result in significant reverse leakage current in a multi-junction VCSEL, and/or the ion implantation may create point defects that may lead to long-term reliability issues. Additionally, the ion implantation and the dicing street etching are additional steps in VCSEL fabrication processes that may increase process complexity and costs.

As a result, VCSEL arrays without ion implantation and dicing streets may be desired. However, a few issues may arise without ion implantation, including current spreading via a highly-doped cap layer to an area between the chip edge and an oxide front in a perimeter of the VCSEL chip. Another issue caused by an absence of ion implantation may include an occurrence of significant leakage current via a sidewall surface at the chip edge due to junctions being damaged by the dicing process. The leakage current can be significant in forward bias with multi-junction VCSELs, since the voltage is much higher. Another issue caused by an absence of ion implantation may include a significant decrease in a reverse breakdown voltage due to junctions being damaged at the chip edge by the dicing process.

Some implementations provide a VCSEL chip that includes a VCSEL array that includes an emitter array region and an edge region that laterally surrounds the emitter array region. The VCSEL chip may be manufactured without an ion implantation. In some implementations, the VCSEL chip may be manufactured without a dicing street. For example, the VCSEL chip may include an isolation trench that is etched in a perimeter of the VCSEL chip to eliminate a need for ion implantation and an etched dicing street. The isolation trench may be provided without adding additional fabrication steps and costs. The isolation trench may be arranged at the edge region of the VCSEL chip, around a perimeter of the emitter array region. The isolation trench may extend through a highly-doped cap layer and into a stacked structure of the VCSEL chip, including extending partially into a bottom DBR mirror. The isolation trench may extend through and/or make contact with one or more oxide layers around peripheral emitters of the VCSEL array. For example, sidewalls of the isolation trench may be in contact with the one or more oxide layers. The isolation trench may block current from spreading from an emitter region of the VCSEL chip into the edge region via the highly-doped cap layer. For example, the isolation trench may form a current barrier with the one or more oxide layers such that the current is prevented from spreading from the emitter region into the edge region via the highly-doped cap layer. The isolation trench need not be parallel to the chip edges.

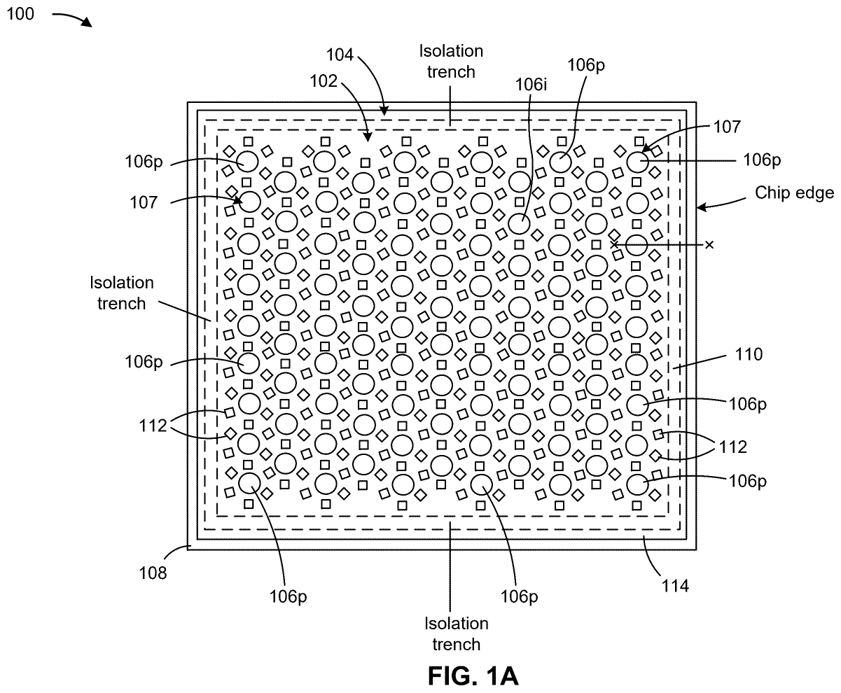

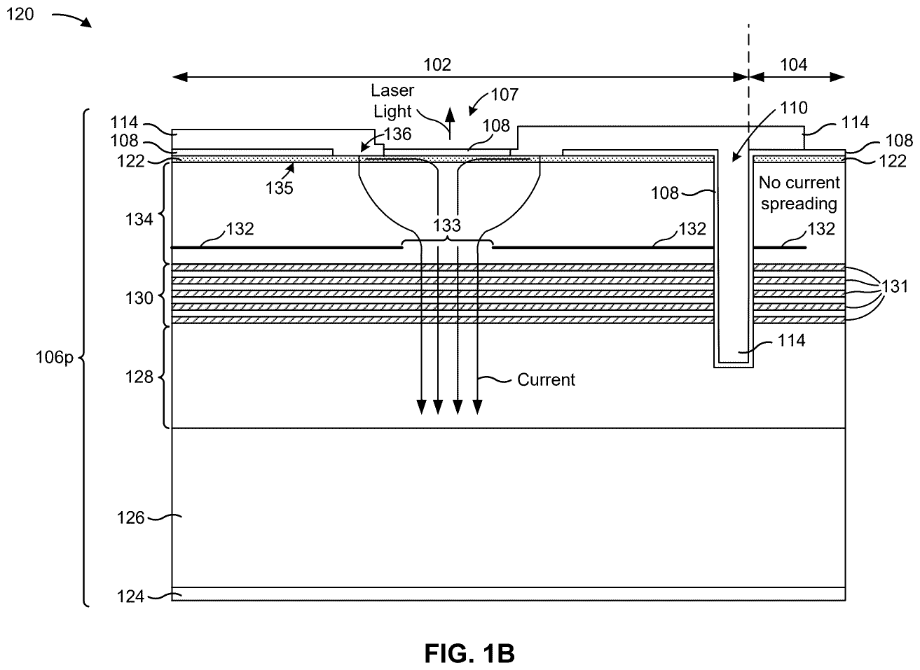

FIG. 1A shows a top view of a VCSEL chip 100 according to one or more implementations. The VCSEL chip 100 may be a VCSEL array device and may include an emitter array region 102 and an edge region 104 that laterally surrounds the emitter array region 102. The edge region 104 may be a region that is laterally adjacent to chip edges of the VCSEL chip 100. An emitter array may be arranged in the emitter array region 102. The emitter array may include a plurality of emitters 106 (e.g., a plurality of VCSEL emitters) arranged in the emitter array region 102 and that share a semiconductor surface. The semiconductor surface may be a top surface of p-type doped DBR layers provided in the VCSEL chip 100. Thus, the semiconductor surface may be a top surface of a top DBR mirror. The plurality of emitters 106 may include inner emitters 106i and peripheral emitters 106p. The peripheral emitters 106p may be arranged at a periphery of the emitter array region 102. The inner emitters 106i may be arranged in an inner region of the emitter array region 102. Each emitter 106 has an optical output 107 (e.g., an optical aperture) from which laser light is emitted.

The VCSEL chip 100 may include one or more dielectric layers 108 and a highly-doped semiconductor layer formed on the semiconductor surface. The highly-doped semiconductor layer may be arranged between the one or more dielectric layers 108 and the semiconductor surface. The highly-doped semiconductor layer may be referred to as a highly-doped cap layer, and may be a p-type doped layer (e.g., a p+layer) that enables current spreading within the emitter array region 102 (e.g., in the emitting area corresponding to optical output 107).

The VCSEL chip 100 may include an isolation trench 110 that laterally surrounds the emitter array region 102. In other words, the isolation trench 110 may encircle the emitter array region 102 in an area between the emitter array region 102 and the edge region 104. Thus, the isolation trench 110 may laterally separate the emitter array region 102 from the edge region 104. Thus, the peripheral emitters 106p may be adjacent to the isolation trench 110, whereas the inner emitters 106i may be nonadjacent to the isolation trench 110. While the isolation trench 110 is shown to be parallel to the chip edges, the isolation trench 110 need not be parallel to the chip edges.

The isolation trench 110 may extend through the highly-doped semiconductor layer and into stacked structures of the peripheral emitters 106p. For example, the isolation trench 110 may extend through a top DBR mirror, through an active region, and partially through a bottom DBR mirror of each peripheral emitter 106p. The isolation trench 110 may extend through and/or make contact with one or more oxide layers. For example, the isolation trench 110 may be in contact with lateral edges of the one or more oxide layers. The isolation trench 110 may be at least partially filled or covered with the one or more dielectric layers 108. The isolation trench 110 may block one or more currents from spreading, via the highly-doped semiconductor layer, from the emitter array region 102 into the edge region 104 where there is no oxide layer present for current confinement. The isolation trench 110 overlaps or intersects with the one or more oxide layers of the peripheral emitters 106p such that there is no current path between the highly-doped semiconductor layer and n-type doped DBR layers in the edge region 104. Moreover, the isolation trench 110 may prevent defects, such as edge defects, present in the edge region 104 from propagating into the emitter array region 102. The defects may be caused during a wafer dicing process step (e.g., during die separation). Thus, the isolation trench 110 may prevent defects present at an outer edge of the stacked structure of the VCSEL chip 100 from propagating into active areas of the emitter array region 102.

The VCSEL chip 100 may include a plurality of oxidation trenches 112 that extend from the semiconductor surface into the emitter array region 102 to expose one or more pre-oxide layers for oxidation that, when oxidized, form the one or more oxide layers and an oxide aperture of each emitter 106. A pre-oxide layer may be an epitaxial layer that is configured for oxidation. For example, a pre-oxide layer may be an aluminum-based layer, such as an AlAs layer or an AlGaAs layer, with high aluminum concentration. The pre-oxide layer may have a higher aluminum concentration than other epitaxial layers. When a pre-oxide layer is exposed to oxygen (e.g., during an oxidation process step), the pre-oxide layer may be converted into an oxide layer. For example, the plurality of oxidation trenches 112 may extend from a top surface of a top DBR mirror of the emitter array region 102 into a stacked structure of the VCSEL chip 100 to expose the one or more pre-oxide layers for oxidation that forms one or more oxide layers and the oxide aperture. Oxidation of a pre-oxide layer may occur for a particular distance toward a center of an emitter 106. A portion of the pre-oxide layer that is not oxidized may form the oxide aperture. Thus, a respective group of oxidation trenches are arranged around a periphery of a respective oxide aperture in an emitting area of the stacked structure in which the respective oxide aperture is formed. The isolation trench 110 may be arranged laterally between the plurality of oxidation trenches 112 and the chip edge of the VCSEL chip 100.

Each oxide aperture may be used for current confinement and optical index guiding in a respective active area. The plurality of oxidation trenches 112 and the isolation trench 110 may be formed in a same etching process step, defined by a same lithographic mask. Thus, an additional process step to form the isolation trench 110 is not needed.

In addition, the plurality of oxidation trenches 112 and the isolation trench 110 may be partially filled with the one or more dielectric layers 108 in a same deposition process step. Thus, an additional process step to partial fill the isolation trench 110 with the one or more dielectric layers 108 is not needed.

In addition, subsequent to forming the one or more dielectric layers 108 in the plurality of oxidation trenches 112 and the isolation trench 110, the plurality of oxidation trenches 112 and the isolation trench 110 may be filled with one or more metal layers 114, such as p-metal layers, that may form an anode contact. The one or more metal layers 114 may form a top structure of the VCSEL chip 100 that is arranged on the highly-doped semiconductor layer and the one or more dielectric layers 108. The one or more metal layers 114 may make contact with the highly-doped semiconductor layer. A metal layer 114 that makes contact with the highly-doped semiconductor layer may be referred to as a contact layer. In addition, the optical output 107 of each emitter 106 may be formed through the one or more metal layers 114 such that laser light can be output from the optical output 107 of each emitter 106. In addition, the plurality of oxidation trenches 112 and the isolation trench 110 may be filled with the one or more metal layers 114 in a same deposition process step. Thus, an additional process step to fill the isolation trench 110 with the one or more metal layers 114 is not needed.

In some implementations, the VCSEL chip 100 is devoid of one or more dicing streets. In some implementations, the VCSEL chip 100 is devoid of a current-blocking ion implantation in the edge region 104. Instead, the isolation trench 110 may render dicing streets and a current-blocking ion implantation in the edge region 104 unnecessary.

As indicated above, FIG. 1A is provided as an example. Other examples may differ from what is described with regard to FIG. 1A.

FIG. 1B shows a cross-sectional view 120 taken along line X-X in FIG. 1A. The cross-sectional view may represent a cross-section of a peripheral emitter 106p that is bisected by the line X-X. Cross-sections of other peripheral emitters 106p provided in the VCSEL chip 100 may be similar to the cross-section shown in FIG. 1B.

The peripheral emitter 106p may include a highly-doped semiconductor layer 122 and a stacked structure on which the highly-doped semiconductor layer 122 is arranged. The stacked structure may include a backside cathode layer 124, a substrate layer 126, a bottom DBR mirror 128, an active region 130, one or more oxide layers 132, and a top DBR mirror 134. The peripheral emitter 106p may further include the one or more dielectric layers 108 and the one or more metal layers 114.

The backside cathode layer 124 may include a layer that makes electrical contact with the substrate layer 126. For example, the backside cathode layer 124 may include an annealed metallization layer, such as an AuGeNi layer, a PdGeAu layer, or the like. In some implementations, the backside cathode layer 124 may be referred to as an n-metal layer. The backside cathode layer 124 may include one or more metal layers.

The substrate layer 126 may include a base substrate layer upon which epitaxial layers are grown. For example, the substrate layer 126 may include a semiconductor layer, such as a GaAs layer, an InP layer, and/or another type of semiconductor layer.

The bottom DBR mirror 128 may include n-doped DBR layers that form a DBR.

The active region 130 (e.g., an active area) may include one or more active layers 131 that confine electrons and define an emission wavelength of the peripheral emitter 106p. For example, the one or more active layers 131 may include one or more junctions, each with one or more quantum wells. The active region 130 may generate laser light to be emitted from the optical output 107 of the peripheral emitter 106p.

The one or more oxide layers 132 may provide optical and electrical confinement of the emitter 106i or 106p. In some implementations, the one or more oxide layers 132 may be formed as a result of wet oxidation of one or more pre-oxide layers (e.g., epitaxial layers with high aluminum concentration). For example, each oxide layer 132 may be an aluminum oxide layer formed as a result of oxidation of a pre-oxide layer. The oxidation trenches 112 may allow oxygen (e.g., dry oxygen, wet oxygen) to access each pre-oxide layer from which the one or more oxide layers 132 are formed.

An oxide aperture 133 (e.g., a current confinement aperture) may include an optically active aperture defined by the one or more oxide layers 132. The oxidation trenches 112 may be etched to expose each pre-oxide layer from which the one or more oxide layers 132 are formed. Oxidation of a pre-oxide layer may occur for a particular distance toward a center of the emitter 106, thereby forming an oxide layer 132 and the oxide aperture 133. Thus, the oxide aperture 133 may be formed by oxidation from the oxidation trenches 112. In other words, the oxide aperture 133 may be formed as a result of the one or more oxide layers 132 being formed by oxidation. The oxide aperture 133 may be formed through the one or more oxide layers 132 to provide current confinement and optical index guiding in the active region 130. In addition, the oxide aperture 133 may be formed below the optical output 107. Similar processes described herein may be used to form each emitter of the emitter array. Moreover, each emitter of the emitter array may be formed simultaneously (e.g., in parallel) with a same sequence of process steps.

The top DBR mirror 134 may include p-doped DBR layers that form a DBR. The top DBR mirror 134 may include a semiconductor surface 135 (e.g., a top surface) on which the highly-doped semiconductor layer 122 is formed. The semiconductor surface 135 may be a shared, top surface that is common to each emitter 106 of the emitter array shown in FIG. 1A.

While the one or more oxide layers 132 are shown to be arranged within the top DBR mirror 134, in some implementations, the one or more oxide layers 132 may be formed within the top DBR mirror 134, within the active region 130 (e.g., between junctions in the active layers 131), and/or within the bottom DBR mirror 128.

The highly-doped semiconductor layer 122 may be referred to as a highly-doped cap layer, and may be a p-type doped layer (e.g., a p+ layer) that enables current spreading laterally within the emitter array region 102.

The one or more dielectric layers 108 may be formed on the highly-doped semiconductor layer 122 and may act as an insulating and protective layer. As shown, the one or more dielectric layers 108 may include one or more vias 136 that provide electrical access to the highly-doped semiconductor layer 122. For example, via 136 may be formed as an etched portion of one or more dielectric layers 108 or a lifted-off section of the one or more dielectric layers 108.

The one or more metal layers 114 may be formed on the one or more dielectric layers 108 in a non-emitting area (e.g., from which the laser light is not emitted). The non-emitting area may be an area not above or laterally offset from the oxide aperture 133. The one or more metal layers 114 may make electrical contact through which electrical current may flow. For example, the one or more metal layers 114 may include a Ti and Au layer, a Ti and Pt layer and/or an Au layer, or the like, through which electrical current may flow (e.g., through a bond pad (not shown) that contacts the one or more metal layers 114 through the via 136 with the highly-doped semiconductor layer 122). The one or more metal layers 114 may be P-ohmic, N-ohmic, or other forms known in the art. Selection of a particular type of metal layer 114 may depend on the architecture of the emitters and is well within the knowledge of a person skilled in the art. The one or more metal layers 114 may provide ohmic contact between a metal and the highly-doped semiconductor layer 122, may provide a non-rectifying electrical junction, and/or may provide a low-resistance contact.

The optical output 107 (e.g., an emitting area) may be arranged over the top DBR mirror 134. In particular, the optical output 107 may be arranged over the oxide aperture 133. The peripheral emitter 106p may emit the laser light via the optical output 107.

The isolation trench 110 may be arranged laterally adjacent to or at the edge region 104. In other words, the isolation trench 110 may be arranged laterally adjacent to the edge region 104, laterally between the emitter array region 102 and the edge region 104, or within the edge region 104. The isolation trench 110 may be arranged laterally adjacent to the peripheral emitter 106p. The isolation trench 110 may extend through the highly-doped semiconductor layer 122 and into the stacked structure, including through the top DBR mirror 134, through the active region 130, and partially into the bottom DBR mirror 128. The isolation trench 110 may extend through and/or make contact with one or more oxide layers 132. For example, the isolation trench may be in contact with the one or more oxide layers 132. The isolation trench 110 may be configured to block current from spreading, via the highly-doped semiconductor layer 122, from the emitter array region 102 into the edge region 104 where no oxide layer is present for current confinement. For example, the isolation trench 110 may form, in combination with one or more of the oxide layers 132, an electrical isolation boundary such that one or more currents generated in the emitter array region 102 do not spread into the edge region 104.

The one or more dielectric layers 108 may be formed on the highly-doped semiconductor layer 122 and within the isolation trench 110. The one or more dielectric layers 108 may be arranged on sidewalls and a bottom surface of the isolation trench 110.

The one or more metal layers 114 may be formed on the one or more dielectric layers 108 and within the isolation trench 110. For example, the one or more dielectric layers 108 may be deposited first to fill a portion of the isolation trench 110 (e.g., to coat or cover the sidewalls and bottom of the isolation trench 110), and the one or more metal layers 114 may be deposited second to fill a remaining portion of the isolation trench 110. Similarly, the one or more dielectric layers 108 and the one or more metal layers 114 may be arranged within the oxidation trenches 112 shown in FIG. 1A. In some implementations, the one or more dielectric layers 108 may be deposited first to fill portions of the isolation trench 110 and the oxidation trenches 112, and the one or more metal layers 114 may be deposited second to fill remaining portions of the isolation trench 110 and the oxidation trenches 112.

The one or more metal layers 114 and the one or more dielectric layers 108 may be provided in the isolation trench 110 and may form a hermetic barrier that prevents moisture penetration to the active region 130 via the one or more oxide layers 132. Moreover, the isolation trench 110 may prevent defects present at an outer edge of the stacked structure (e.g., at the chip edge) from propagating into the emitter array region 102 (e.g., into the active region 130) in device operation.

In some implementations, the VCSEL chip 100 may be manufactured using a series of steps. For example, the bottom DBR mirror 128, the active region 130, the top DBR mirror 134, the epitaxial layers configured for oxidation (e.g., the pre-oxide layers), and the highly-doped semiconductor layer 122 may be epitaxially grown on the substrate layer 126. Next, the isolation trench 110 and the oxidation trenches 112 may be formed in a same etching process step, defined by a same lithographic mask. In some implementations, the isolation trench 110 and the oxidation trenches 112 may be formed in different etching process steps such that the isolation trench 110 is formed prior to forming the oxidation trenches 112, or vice versa. Next, the one or more oxide layers 132 may be formed via oxidation of the epitaxial layers configured for oxidation, which also results in the oxide aperture 133 being formed. Next, the one or more dielectric layers 108 may be formed on the highly-doped semiconductor layer 122 and within the isolation trench 110 and the oxidation trenches 112 in a same deposition process step. The via 136 may be etched in the one or more dielectric layers 108 (e.g., to expose the highly-doped semiconductor layer 122 for ohmic contact). Next, the one or more metal layers 114 may be formed on the one or more dielectric layers 108 and within the isolation trench 110 and the oxidation trenches 112 in a same deposition process step. Plating, seeding, and etching may be performed, after which the substrate layer 126 may be thinned and/or lapped to a target thickness. Finally, the backside cathode layer 124 may be deposited on a bottom side of the substrate layer 126. Dopings may be applied during epitaxial growth within the manufacturing process based on known techniques and process steps. Additional process steps, including process steps that may be performed between the above-described process steps, have been omitted for the sake of simplifying the description of the manufacturing process.

As indicated above, FIG. 1B is provided as an example. Other examples may differ from what is described with regard to FIG. 1B. For example, the number, arrangement, thicknesses, order, symmetry, or the like, of layers shown in FIG. 1B is provided as an example. In practice, the VCSEL chip 100 may include additional layers, fewer layers, different layers, differently constructed layers, or differently arranged layers than those shown in FIG. 1B. Additionally, or alternatively, a set of layers (e.g., one or more layers) of the VCSEL chip 100 may perform one or more functions described as being performed by another set of layers of the VCSEL chip 100 and any layer may comprise one layer or more than one layer.

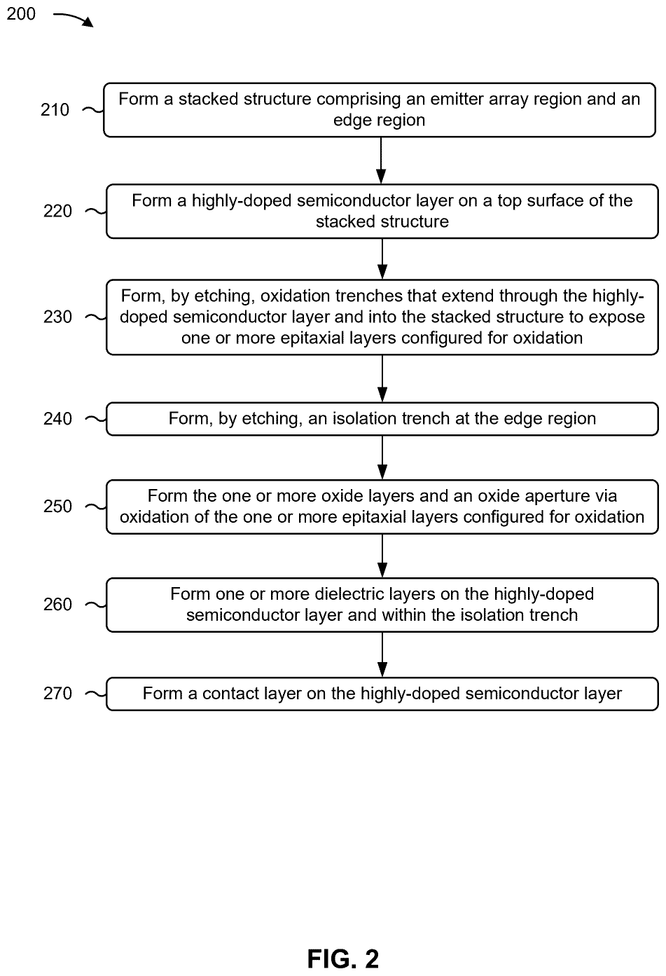

FIG. 2 is a flowchart of an example process 200 associated with vertical cavity surface emitting laser array without implantation. In some implementations, one or more process blocks of FIG. 2 are performed by one or more manufacturing systems and/or one or more manufacturing tools commonly used in semiconductor and emitter manufacturing.

As shown in FIG. 2, process 200 may include forming a stacked structure that includes an emitter array region and an edge region (block 210). The stacked structure may include a bottom DBR mirror; a top DBR mirror having a top surface; one or more active layers arranged between the bottom DBR mirror and the top DBR mirror; and one or more epitaxial layers configured for oxidation, as described above.

As further shown in FIG. 2, process 200 may include forming a highly-doped semiconductor layer on a top surface of the top DBR mirror (block 220).

As further shown in FIG. 2, process 200 may include forming, by etching, oxidation trenches that extend through the highly-doped semiconductor layer and into the stacked structure to expose the one or more epitaxial layers for oxidation (block 230).

As further shown in FIG. 2, process 200 may include forming, by etching, an isolation trench at the edge region (block 240). The isolation trench may extend through the highly-doped semiconductor layer and into the stacked structure, including partially into the bottom DBR mirror, as described above. The isolation trench may be configured to block current from spreading from the emitter array region into the edge region, as described above.

As further shown in FIG. 2, process 200 may include forming the one or more oxide layers and an oxide aperture via oxidation of the one or more epitaxial layers configured for oxidation (block 250). The oxide aperture may be configured for current confinement and optical index guiding, as described above.

As further shown in FIG. 2, process 200 may include forming one or more dielectric layers on the highly-doped semiconductor layer and within the isolation trench (block 260).

As further shown in FIG. 2, process 200 may include forming a contact layer on the highly-doped semiconductor layer (block 270).

Process 200 may include additional implementations, such as any single implementation or any combination of implementations described below and/or in connection with one or more other processes described elsewhere herein.

In a first implementation, the isolation trench is in contact with the one or more oxide layers.

In a second implementation, the isolation trench intersects with the one or more oxide layers.

In a third implementation, forming the isolation trench includes forming the isolation trench through the top DBR mirror, through the one or more epitaxial layers configured for oxidation, and through the one or more active layers.

In a fourth implementation, the oxidation trenches and the isolation trench are formed in a same etching process step, defined by a same lithographic mask.

In a fifth implementation, forming the one or more dielectric layers includes forming the one or more dielectric layers within the oxidation trenches, wherein the one or more dielectric layers are arranged on sidewalls and bottom surfaces of the isolation trench and the oxidation trenches.

In a sixth implementation, process 200 includes forming one or more metal layers on the one or more dielectric layers and within the isolation trench and the one or more oxidation trenches, wherein the one or more metal layers fill remaining portions of the isolation trench and the oxidation trenches.

Although FIG. 2 shows example blocks of process 200, in some implementations, process 200 includes additional blocks, fewer blocks, different blocks, or differently arranged blocks than those depicted in FIG. 2. Additionally, or alternatively, two or more of the blocks of process 200 may be performed in parallel as a same step or as parallel steps.

The following provides an overview of some Aspects of the present disclosure:

Aspect 1: A VCSEL emitter device, comprising: a highly-doped cap layer; a stacked structure comprising a top surface and an edge region, wherein the highly-doped cap layer is arranged on the top surface, and wherein the stacked structure comprises: a bottom DBR mirror; a top DBR mirror arranged on the bottom DBR mirror; an active area formed by one or more active layers comprising one or more junctions, each junction including one or more quantum wells, wherein the active area is configured to generate laser light, and wherein the active area is arranged between the top DBR mirror and the bottom DBR mirror; and one or more oxide layers, wherein an oxide aperture is formed through the one or more oxide layers for current confinement and optical index guiding; and an isolation trench arranged at the edge region, wherein the isolation trench extends through the highly-doped cap layer and into the stacked structure, including contacting the one or more oxide layers and extending partially into the bottom DBR mirror, and wherein the isolation trench is configured to block current from spreading into the edge region via the highly-doped cap layer.

Aspect 2: The VCSEL emitter device of Aspect 1, further comprising: a dielectric layer arranged on the top surface and within the isolation trench, wherein the dielectric layer is arranged on sidewalls and a bottom surface of the isolation trench.

Aspect 3: The VCSEL emitter device of Aspect 2, further comprising: one or more metal layers arranged on the dielectric layer in a non-emitting area, and arranged within the isolation trench.

Aspect 4: The VCSEL emitter device of Aspect 3, wherein the one or more metal layers and the dielectric layer are provided in the isolation trench and form a hermetic barrier that prevents moisture penetration to the active area via the one or more oxide layers.

Aspect 5: The VCSEL emitter device of any of Aspects 1-4, wherein the isolation trench is configured to prevent defects present at an outer edge of the stacked structure from propagating into the active area.

Aspect 6: The VCSEL emitter device of Aspect 5, wherein the isolation trench laterally separates the edge region from the active area.

Aspect 7: The VCSEL emitter device of any of Aspects 1-6, further comprising: a plurality of oxidation trenches that extend from the top surface into the stacked structure to expose the one or more oxide layers for oxidation that forms the oxide aperture, wherein the plurality of oxidation trenches are arranged around a periphery of the oxide aperture in an emitting area of the stacked structure in which the oxide aperture is formed, and wherein the isolation trench is arranged laterally between the plurality of oxidation trenches and a chip edge of the VCSEL emitter device.

Aspect 8: The VCSEL emitter device of Aspect 7, further comprising: a dielectric layer arranged on the top surface, within the isolation trench, and within the plurality of oxidation trenches, wherein the dielectric layer lines sidewalls and bottom surfaces of the isolation trench and the plurality of oxidation trenches; and one or more metal layers arranged on the dielectric layer, and arranged within the isolation trench and the plurality of oxidation trenches.

Aspect 9: The VCSEL emitter device of any of Aspects 1-8, wherein the isolation trench extends through the one or more oxide layers.

Aspect 10: A VCSEL array device, comprising: an emitter array region and an edge region that laterally surrounds the emitter array region; an emitter array comprising a plurality of emitters arranged in the emitter array region and that share a semiconductor surface, wherein the plurality of emitters include a plurality of peripheral emitters arranged at a periphery of the emitter array region, wherein each emitter of the plurality of emitters includes: a stacked structure comprising: a top DBR mirror; a bottom DBR mirror arranged on the top DBR mirror; an active area formed by one or more active layers comprising one or more junctions, each junction including one or more quantum wells, wherein the active area is configured to generate laser light, and wherein the active area is arranged between the top DBR mirror and the bottom DBR mirror; and one or more oxide layers, wherein an oxide aperture is formed through the one or more oxide layers for current confinement and optical index guiding in the active area; a highly-doped semiconductor layer arranged on the semiconductor surface for current spreading laterally in the emitter array region; and an optical output arranged over the top DBR mirror, wherein the emitter is configured to emit the laser light via the optical output; and an isolation trench that laterally surrounds the emitter array region, wherein the isolation trench laterally separates the emitter array region from the edge region, wherein the isolation trench extends through the highly-doped semiconductor layer into the stacked structure, including extending through the top DBR mirror, extending through the one or more active layers, contacting the one or more oxide layers, and extending partially through the bottom DBR mirror of each peripheral emitter of the plurality of peripheral emitters, and wherein the isolation trench is configured to block one or more currents from spreading from the emitter array region into the edge region where there is no oxide layer present for current confinement.

Aspect 11: The VCSEL device of Aspect 10, further comprising: a dielectric layer arranged on the semiconductor surface and within the isolation trench, wherein the dielectric layer is arranged on sidewalls and a bottom surface of the isolation trench.

Aspect 12: The VCSEL device of Aspect 11, further comprising: one or more metal layers arranged on the dielectric layer, and arranged within the isolation trench, wherein the one or more metal layers fill a remaining portion of the isolation trench.

Aspect 13: The VCSEL device of Aspect 12, wherein the dielectric layer and the one or more metal layers form a hermetic structure.

Aspect 14: The VCSEL device of any of Aspects 10-13, wherein the isolation trench is configured to prevent edge defects present in the edge region from propagating into the emitter array region.

Aspect 15: The VCSEL device of any of Aspects 10-14, further comprising: a plurality of oxidation trenches that extend from the semiconductor surface into the emitter array region to expose the one or more oxide layers of each emitter of the plurality of emitters for oxidation that forms the oxide aperture of each emitter of the plurality of emitters, one or more dielectric layers arranged on the semiconductor surface, within the isolation trench, and within the plurality of oxidation trenches, wherein the one or more dielectric layers line sidewalls and bottom surfaces of the isolation trench and the plurality of oxidation trenches; and one or more metal layers arranged on the one or more dielectric layers, and arranged within the isolation trench and the plurality of oxidation trenches, wherein the one or more metal layers fill remaining portions of the isolation trench and the plurality of oxidation trenches.

Aspect 16: The VCSEL device of any of Aspects 10-15, wherein the VCSEL device is devoid of a dicing street.

Aspect 17: The VCSEL device of any of Aspects 10-16, wherein the VCSEL device is devoid of a current-blocking ion implantation in the edge region.

Aspect 18: The VCSEL device of Aspect 1, wherein the isolation trench extends through the one or more oxide layers of each peripheral emitter of the plurality of peripheral emitters.

Aspect 19: A method of manufacturing an emitter, the method comprising: forming a stacked structure comprising an emitter array region and an edge region, wherein the stacked structure comprises: a bottom DBR mirror; a top DBR mirror having a top surface; one or more active layers arranged between the bottom DBR mirror and the top DBR mirror; and one or more epitaxial layers configured for oxidation; forming a highly-doped semiconductor layer on the top surface; forming, by etching, oxidation trenches that extend through the highly-doped semiconductor layer and into the stacked structure to expose the one or more epitaxial layers for oxidation; forming, by etching, an isolation trench at the edge region, wherein the isolation trench extends through the highly-doped semiconductor layer and into the stacked structure, including partially into the bottom DBR mirror, and wherein the isolation trench is configured to block current from spreading from the emitter array region into the edge region; forming the one or more oxide layers and an oxide aperture via oxidation of the one or more epitaxial layers configured for oxidation, wherein the oxide aperture is configured for current confinement and optical index guiding; forming one or more dielectric layers on the highly-doped semiconductor layer and within the isolation trench; and forming a contact layer on the highly-doped semiconductor layer.

Aspect 20: The method of Aspect 19, wherein the isolation trench is in contact with the one or more oxide layers.

Aspect 21: The method of any of Aspects 19-20, wherein the isolation trench intersects with the one or more oxide layers.

Aspect 22: The method of any of Aspects 19-21, wherein forming the isolation trench includes forming the isolation trench through the top DBR mirror, through the one or more epitaxial layers configured for oxidation, and through the one or more active layers.

Aspect 23: The method of any of Aspects 19-22, wherein the oxidation trenches and the isolation trench are formed in a same etching process step, defined by a same lithographic mask.

Aspect 24: The method of any of Aspects 19-23, further comprising: forming the one or more dielectric layers includes forming the one or more dielectric layers within the oxidation trenches, wherein the one or more dielectric layers are arranged on sidewalls and bottom surfaces of the isolation trench and the oxidation trenches.

Aspect 25: The method of Aspect 24, further comprising: forming one or more metal layers on the one or more dielectric layers and within the isolation trench and the one or more oxidation trenches, wherein the one or more metal layers fill remaining portions of the isolation trench and the oxidation trenches.

Aspect 26: A system configured to perform one or more operations recited in one or more of Aspects 1-25.

Aspect 27: An apparatus comprising means for performing one or more operations recited in one or more of Aspects 1-25.

Aspect 28: A non-transitory computer-readable medium storing a set of instructions, the set of instructions comprising one or more instructions that, when executed by a device, cause the device to perform one or more operations recited in one or more of Aspects 1-25.

Aspect 29: A computer program product comprising instructions or code for executing one or more operations recited in one or more of Aspects 1-25.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL) emitter device, comprising:
a highly-doped cap layer;
a stacked structure comprising a top surface and an edge region, wherein the highly-doped cap layer is arranged on the top surface, and wherein the stacked structure comprises:
a bottom distributed Bragg reflector (DBR) mirror;
a top DBR mirror arranged on the bottom DBR mirror;
an active area formed by one or more active layers comprising one or more junctions, each junction including one or more quantum wells, wherein the active area is configured to generate laser light, and wherein the active area is arranged between the top DBR mirror and the bottom DBR mirror; and
one or more oxide layers, wherein an oxide aperture is formed through the one or more oxide layers for current confinement and optical index guiding; and
an isolation trench arranged at the edge region, wherein the isolation trench extends through the highly-doped cap layer and into the stacked structure, including contacting the one or more oxide layers and extending partially into the bottom DBR mirror, and wherein the isolation trench is configured to block current from spreading into the edge region via the highly-doped cap layer.

2. The VCSEL emitter device of claim 1, further comprising:
a dielectric layer arranged on the top surface and within the isolation trench,
wherein the dielectric layer is arranged on sidewalls and a bottom surface of the isolation trench.

3. The VCSEL emitter device of claim 2, further comprising:
one or more metal layers arranged on the dielectric layer in a non-emitting area, and arranged within the isolation trench.

4. The VCSEL emitter device of claim 3, wherein the one or more metal layers and the dielectric layer are provided in the isolation trench and form a hermetic barrier that prevents moisture penetration to the active area via the one or more oxide layers.

5. The VCSEL emitter device of claim 1, wherein the isolation trench is configured to prevent defects present at an outer edge of the stacked structure from propagating into the active area.

6. The VCSEL emitter device of claim 5, wherein the isolation trench laterally separates the edge region from the active area.

7. The VCSEL emitter device of claim 1, further comprising:
a plurality of oxidation trenches that extend from the top surface into the stacked structure to expose the one or more oxide layers for oxidation that forms the oxide aperture,
wherein the plurality of oxidation trenches are arranged around a periphery of the oxide aperture in an emitting area of the stacked structure in which the oxide aperture is formed, and
wherein the isolation trench is arranged laterally between the plurality of oxidation trenches and a chip edge of the VCSEL emitter device.

8. The VCSEL emitter device of claim 7, further comprising:
a dielectric layer arranged on the top surface, within the isolation trench, and within the plurality of oxidation trenches, wherein the dielectric layer lines sidewalls and bottom surfaces of the isolation trench and the plurality of oxidation trenches; and
one or more metal layers arranged on the dielectric layer, and arranged within the isolation trench and the plurality of oxidation trenches.

9. The VCSEL emitter device of claim 1, wherein the isolation trench extends through the one or more oxide layers.

10. A vertical-cavity surface-emitting laser (VCSEL) array device, comprising:
an emitter array region and an edge region that laterally surrounds the emitter array region;
an emitter array comprising a plurality of emitters arranged in the emitter array region and that share a semiconductor surface, wherein the plurality of emitters include a plurality of peripheral emitters arranged at a periphery of the emitter array region, wherein each emitter of the plurality of emitters includes:
a stacked structure comprising:
a top distributed Bragg reflector (DBR) mirror;
a bottom DBR mirror arranged on the top DBR mirror;
an active area formed by one or more active layers comprising one or more junctions, each junction including one or more quantum wells, wherein the active area is configured to generate laser light, and wherein the active area is arranged between the top DBR mirror and the bottom DBR mirror; and
one or more oxide layers, wherein an oxide aperture is formed through the one or more oxide layers for current confinement and optical index guiding in the active area;
a highly-doped semiconductor layer arranged on the semiconductor surface for current spreading laterally in the emitter array region; and
an optical output arranged over the top DBR mirror, wherein the emitter is configured to emit the laser light via the optical output; and
an isolation trench that laterally surrounds the emitter array region, wherein the isolation trench laterally separates the emitter array region from the edge region, wherein the isolation trench extends through the highly-doped semiconductor layer into the stacked structure, including extending through the top DBR mirror, extending through the one or more active layers, contacting the one or more oxide layers, and extending partially through the bottom DBR mirror of each peripheral emitter of the plurality of peripheral emitters, and wherein the isolation trench is configured to block one or more currents from spreading from the emitter array region into the edge region where there is no oxide layer present for current confinement.

11. The VCSEL array device of claim 10, further comprising:
a dielectric layer arranged on the semiconductor surface and within the isolation trench,
wherein the dielectric layer is arranged on sidewalls and a bottom surface of the isolation trench.

12. The VCSEL array device of claim 11, further comprising:
one or more metal layers arranged on the dielectric layer, and arranged within the isolation trench,
wherein the one or more metal layers fill a remaining portion of the isolation trench.

13. The VCSEL array device of claim 12, wherein the dielectric layer and the one or more metal layers form a hermetic structure.

14. The VCSEL array device of claim 10, wherein the isolation trench is configured to prevent edge defects present in the edge region from propagating into the emitter array region.

15. The VCSEL array device of claim 10, further comprising:
a plurality of oxidation trenches that extend from the semiconductor surface into the emitter array region to expose the one or more oxide layers of each emitter of the plurality of emitters for oxidation that forms the oxide aperture of each emitter of the plurality of emitters,
one or more dielectric layers arranged on the semiconductor surface, within the isolation trench, and within the plurality of oxidation trenches, wherein the one or more dielectric layers line sidewalls and bottom surfaces of the isolation trench and the plurality of oxidation trenches; and
one or more metal layers arranged on the one or more dielectric layers, and arranged within the isolation trench and the plurality of oxidation trenches,
wherein the one or more metal layers fill remaining portions of the isolation trench and the plurality of oxidation trenches.

16. The VCSEL array device of claim 10, wherein the VCSEL device is devoid of a dicing street.

17. The VCSEL array device of claim 10, wherein the VCSEL device is devoid of a current-blocking ion implantation in the edge region.

18. The VCSEL array device of claim 10, wherein the isolation trench extends through the one or more oxide layers of each peripheral emitter of the plurality of peripheral emitters.

19. A method of manufacturing a vertical-cavity surface-emitting laser (VCSEL) array device, the method comprising:
forming a stacked structure comprising an emitter array region and an edge region, wherein the stacked structure comprises:
a bottom distributed Bragg reflector (DBR) mirror;
a top DBR mirror having a top surface;
one or more active layers arranged between the bottom DBR mirror and the top DBR mirror; and
one or more epitaxial layers configured for oxidation;
forming a highly-doped semiconductor layer on the top surface;
forming, by etching, oxidation trenches that extend through the highly-doped semiconductor layer and into the stacked structure to expose the one or more epitaxial layers for oxidation;
forming, by etching, an isolation trench at the edge region, wherein the isolation trench extends through the highly-doped semiconductor layer and into the stacked structure, including partially into the bottom DBR mirror, and wherein the isolation trench is configured to block current from spreading from the emitter array region into the edge region;
forming the one or more oxide layers and an oxide aperture via oxidation of the one or more epitaxial layers configured for oxidation, wherein the oxide aperture is configured for current confinement and optical index guiding;
forming one or more dielectric layers on the highly-doped semiconductor layer and within the isolation trench; and
forming a contact layer on the highly-doped semiconductor layer.

20. The method of claim 19, wherein the isolation trench is in contact with the one or more oxide layers.

21. The method of claim 19, wherein the isolation trench intersects with the one or more oxide layers.

22. The method of claim 19, wherein forming the isolation trench includes forming the isolation trench through the top DBR mirror, through the one or more epitaxial layers configured for oxidation, and through the one or more active layers.

23. The method of claim 19, wherein the oxidation trenches and the isolation trench are formed in a same etching process step, defined by a same lithographic mask.

24. The method of claim 19, further comprising:
forming the one or more dielectric layers includes forming the one or more dielectric layers within the oxidation trenches,
wherein the one or more dielectric layers are arranged on sidewalls and bottom surfaces of the isolation trench and the oxidation trenches.

25. The method of claim 24, further comprising:
forming one or more metal layers on the one or more dielectric layers and within the isolation trench and the one or more oxidation trenches,
wherein the one or more metal layers fill remaining portions of the isolation trench and the oxidation trenches.
